(19) United States
(12) Patent Application Publication
(10) Pub. No.: US 2006/0141667 A1
(43) Pub. Date: Jun. 29, 2006

(54) Bare die socket

(75) Inventors: Donald W. Milbrand JR., Bristol, NH (US); Mark W. Gailus, Somerville, MA (US); Nathan W. Pascarella, Milford, NH (US)

Correspondence Address: Edmund J. Walsh;Wolf, Greenfield & Sacks, P.C., 600 Atlantic Avenue, Boston, MA, 02210-2206, US

(73) Assignee: Teradyne, Inc., Boston, MA (US)

(21) Appl. No.: 11/053,448

(22) Filed: Feb. 8, 2005

Related U.S. Application Data
(60) Provisional application No. 60/639,064, filed on Dec. 23, 2004.

(51) Int. Cl. H01L 21/44

(52) U.S. Cl. 438/106

(57) ABSTRACT

A socket for removably mounting a bare die to a substrate, such as a printed circuit board. This socket is formed by insert molding signal conductors in an insulative housing. A ground structure is separately provided to control the impedance of the signal conductors and to reduce cross talk. The ground structure may be formed as a separate subassembly and attached to the subassembly formed by insert molding a housing around signal conductors. The ground structure also provides ground connections between the printed circuit board and the chip.

### RELATED APPLICATIONS

This application claims priority under 35 U.S.C. § 119(e) to U.S. Provisional Application Ser. No. 60/639,064, entitled “BARE DIE SOCKET,” filed on Dec. 23, 2004, which is herein incorporated by reference in its entirety.

### BACKGROUND OF INVENTION

1. Field of Invention

The invention relates generally to chip sockets and more specifically to a chip socket suitable for attaching a bare die to a substrate.

2. Discussion of Related Art

Semiconductor integrated circuits are generally formed on a small piece of silicon, referred to as a die. Circuits are formed in the die by either implanting material into the silicon or depositing material onto the silicon. The features implanted in or deposited on the silicon can be made very small. Conductive pads that are connected to the circuit elements in the integrated circuit may be formed on the surface of the die. However, these pads have been traditionally been too small to be used to make reliable connections to the integrated circuit when it is assembled into an electronic system.

Rather, in most instances, the die is placed in a package that is usually much larger than the die. The package includes multiple leads that run from the inside of the package to the outside. Before the package is sealed, specialized equipment is used to connect bond wires from the pads on the surface of the die to the leads. The leads outside the package are larger and facilitate more robust connections between the integrated circuit and other components in an electronic system in which the integrated circuit is installed.

More recently, some chip packages have included small printed circuit boards. The chip is attached to the printed circuit board. Then external leads are connected to the printed circuit board. In some instances, the external leads are connected directly to the small printed circuit board inside the package. For example, leads in the form of solder balls may be attached directly to the small printed circuit board. In other instances, bond wires are employed to connect the small printed circuit board to the external leads.

It is sometimes desirable to use bond wires in a semiconductor package because the bond wires are flexible. The semiconductor material from which the chip is formed usually has a coefficient of thermal expansion that is different than the substrate in an electronic system to which the integrated circuit device is attached. As the semiconductor device heats up, the chip and the substrate often expand at different rates. Any rigid connection between the chip and the substrate may become stressed and fail. Accordingly, flexible connections, such as those provided by bond wires, may increase the reliability of the device.

Where small printed circuit boards are used inside the package, flip-chip mounting has sometimes been used. Flip chip mounting is done by forming very small solder balls, sometimes called “microballs,” on the pads on the surface of the die. This surface of the die is then positioned to face the small circuit board, which has an array of pads that match the array of solder balls on the surface of the die. When the assembly is heated, the solder balls reflow and adhere the chip to the small printed circuit board.

In some instances, the intermediate steps of mounting the chip to a small printed circuit board inside a package is omitted. Chip on Board (COB) technology is used to mount the semiconductor die, without an intermediate package, to the substrate in an electronic system. Often, the substrate is a large printed circuit board that includes many other semiconductor devices.

A semiconductor die without intermediate packaging is sometimes referred to as a bare die. Bare die attachment is sometimes desirable because bare dies are smaller than packaged parts. Bare dies are also less expensive to manufacture than packaged parts. However, there are drawbacks associated with the use of COB mounting. One drawback is that the large printed circuit board must be manufactured with very small pads on it to align with the pads on the die. Microballs are often positioned in an array with spacing of 0.5 mm or less. Making a printed circuit board with such small features can increase the cost of the printed circuit board—which may nullify any cost savings of using a bare die. The small mounting can also be more fragile and therefore more prone to damage or defects. Further, COB mounting is done without any bond wires or intermediate structures, which can make the mounting susceptible to failure due to thermal cycling. Also, printed circuit boards formed with COB mounting are generally not easily repairable.

As a result, COB mounting has been used in only a limited number of situations, such as the manufacture of small devices using inexpensive integrated circuits.

It would be desirable to provide a practical way to use bare dies in other applications.

### SUMMARY OF INVENTION

In one aspect, the invention relates to a method of manufacturing a chip socket. The method includes providing a plurality of conductive members, each having a first contact portion, a second contact portion and an intermediate portion coupled between the first contact portion and the second contact portion. Additionally, the method includes molding insulative material over the intermediate portions of the plurality of conductive members, the insulative material shaped with a first major surface and a second major surface, opposite the first major surface, the insulative material molded to leave the first contact portions of each of the plurality of conductive members exposed in the first major surface of the insulative material and to leave the second contact portions of each of the plurality of conductive members exposed in the second major surface of the insulative material.

In another aspect, the invention relates to a chip socket that has an insulative housing and a plurality of conductive members. Each of the conductive members has a first contact portion and a second contact portion and an intermediate portion coupled between the first contact portion and the second contact portion. The plurality of conductive members are positioned with the intermediate portions of the plurality of conductive members disposed in a plane within the insulative housing and the first contact portion extending from the plane in a first direction and the second contact portion extending from the plane in a second direction, opposite the first direction.

In another aspect, the invention relates to a chip socket comprising a plurality of conductive members, each of the plurality of conductive members having an first contact portion, a second contact portion and an intermediate portion coupled between the first contact portion and the second contact portion, with the intermediate portions of the plurality of conductive members disposed in a plane with the first contact portion of each of the plurality of conductive members extending from a first side of the plane and the second contact portion of each of the plurality of conductive members extending from a second side of the plane. The socket also has a conductive structure having a portion positioned in a second plane parallel to the plane, the conductive structure having a plurality of first contact portions and a plurality of second contact portions, with the plurality of first contact portions extending from the first side of the plane and the plurality of second contact portions extending from the second side of the second plane.

### BRIEF DESCRIPTION OF DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1 is a sketch of an integrated circuit chip attached to a substrate using a socket according to the invention;

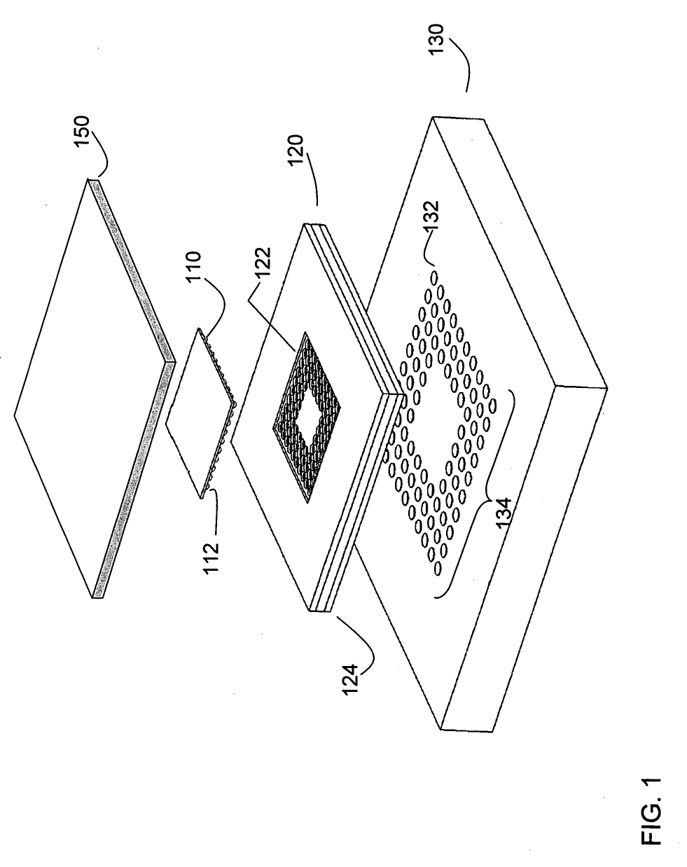

FIG. 2 is an enlarged view of a portion of a lower surface of the chip socket of FIG. 1;

FIG. 3 is an exploded view of the chip socket of FIG. 1; and

FIG. 4 is a side view of the chip socket in FIG. 3.

### DETAILED DESCRIPTION

This invention is not limited in its application to the details of construction and the arrangement of components set forth in the following description or illustrated in the drawings. The invention is capable of other embodiments and of being practiced or of being carried out in various ways. Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

The invention is here illustrated by a socket 120 used to attach a chip 110 to a substrate, such as circuit board 130. Here, chip 110 is a semiconductor device that includes solder balls 112 for making connections to circuits within the chip 110. In the illustrated embodiment, chip 110 is an unpackaged device and solder balls 112 may be in the form sometimes referred to as “microballs.” Chips in this format are sometimes referred to as “flip chips” or “bumped die.”

Socket 120 includes a cavity 122 that is sized to receive chip 110. With chip 110 inserted in cavity 122, a cover 150 may be applied to socket 120. Cover 150 may be formed from a material that has a high thermal conductivity, such as metal. In this embodiment, cover 150 may serve as a heat sink to remove heat generated by the operation of the chip 110 or may provide a thermally conductive path to a heat sink (not shown) mounted on cover 150.

Gasket material (not shown) may optionally be included at the interface between cover 150 and socket 120. Gasket material may provide environmental protection for chip 110 while mounted in socket 120 and may, for example, prevent contaminants from interfering with the electrical connections between socket 120 and chip 110. Gasket material may also form a seal that reduces the amount of oxygen, chlorine, sulfur or other oxidizing gasses reaching the conductive contacts members of socket 120 or chip 110. Such gasses may cause non-conductive oxides to form on conductive contact members, which may reduce the reliability of electrical connections formed within socket 120.

Cover 150 may be mounted to socket 120 in any suitable way. It may be mounted with a permanent or semi-permanent mounting, such as an adhesive. Alternatively, cover 150 may be installed using a mechanism that allows cover 150 to be readily removed. For example, socket 120 may be constructed with a lever or other structure that forces cover 150 against socket 120. Regardless of the specific mechanism used to mount cover 150, cover 150 may be used to press chip 110 against socket 120. Pressure on chip 110 facilitates a reliable electrical connection between solder balls 112 and contact members within socket 120.

Socket 120 is attached to circuit board 130 with lower surface 124 facing circuit board 130. Circuit board 130 may be a conventional printed circuit board. However, socket 120 may be attached to any type of substrate used in an electronic system. In some embodiments, socket 120 may be permanently attached to circuit board 130. For example, socket 120 may be attached to circuit board 130 by soldering using BGA or surface mount techniques. Alternatively, socket 120 may be attached to circuit board 130 using pressure mount, through hole, or other semipermanent or removable mounting techniques. Where pressure mounting is required, circuit board 130 may include a mechanism to press socket 120 against circuit board 130 to generate the required contact force. Where socket 120 is mounted to circuit board 130 using a pressure mounting technique, the same mechanism may be used to press cover 150 against socket 120 as is used to press socket 120 against surface board 130.

Circuit board 130 includes an array 134 of contact points 132. Here the contact points are pads 132 on the surface of circuit board 130. Each of the pads 132 may be a pad as conventionally used in the manufacture of printed circuit boards. Each pad 132 may be connected through a via to conductive traces (not shown) within circuit board 130.

Socket 120 includes contacts on lower surface 124 that are coupled to pads 132 in the array 134. Each of the contacts is a portion of a conductive path through socket 120 that includes a second contact positioned to mate with one of the solder balls 112 on chip 110. In this way, electrical connections are provided between each of the solder balls 112 on chip 110 and a pad 132 on circuit board 130.

Use of socket 120 provides advantages as compared to directly attaching chip 110 to circuit board 130. Socket 120 allows chip 110 to be easily removed after it is mounted to circuit board 130. Such a removable mounting facilitates repair or upgrade of an electronic system in which circuit board 130 is used. Further, the contacts on the lower surface 124 of socket 120 are positioned in an array 134 that is larger than chip 110. Solder balls 112 are positioned in an array with spacing between balls that could be 0.5 mm or less. The cost and risk of manufacturing defects that result from making a printed circuit board with an array of pads spaced 0.5 mm or less is avoided through the use of socket 120. In some embodiments, the on-center spacing of pads within array 134 will be 0.9 mm or more. In some embodiments, the on-center spacing between pads will be approximately 1 mm. In other embodiments, the spacing will be about 1.27 mm. These dimensions represent dimensions that can be achieved with readily available surface mount manufacturing technology.

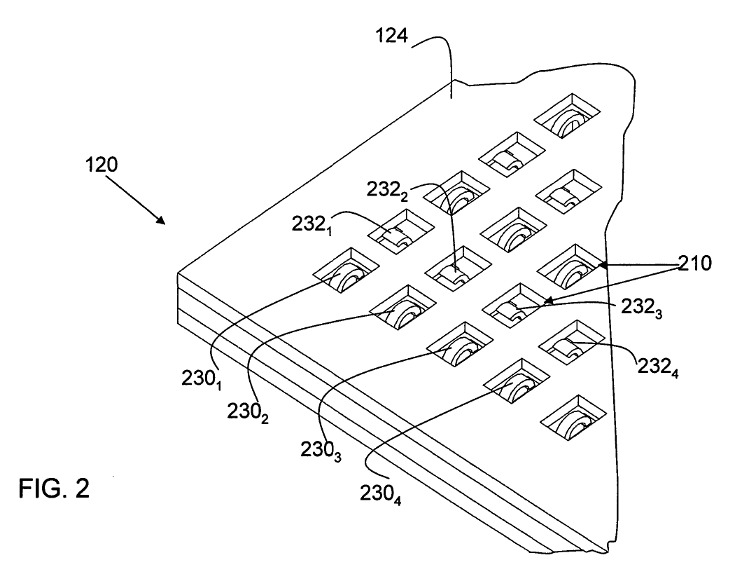

Turning now to FIG. 2, lower surface 124 of socket 120 is shown. Lower surface 124 is formed with multiple windows 210. The windows 210 expose contacts. In FIG. 2, contacts such as 230₁, 230₂ . . . 230₄ and contacts 232₁, 232₂ . . . 232₄ are indicated. In the illustrated embodiment, socket 120 includes a contact to align with each of the pads 132 on circuit board 130.

In the described embodiment, some of the contacts are positioned to connect to pads 132 that connect to traces within circuit board 130 that carry signals to chip 110. Others of the contacts are positioned to mate with pads 132 that connect internally to ground structures within circuit board 130. As used herein, “ground” refers to any point connected to a DC or low frequency signal even if not directly connected to earth ground.

In the illustrated embodiment, the contacts are positioned in rows with contacts 230₁ . . . 230₄ occupying one row and contacts 232₁ . . . 232₄ occupying a second row. In the embodiment shown, all of the contacts in the rows occupied by contacts 232₁ . . . 232₄ are ground contacts. All of the contacts in the row occupied by contacts 230₁ . . . 230₄ are signal contacts. This pattern of interleaving rows of ground and signal contacts may be repeated across the entire socket 120. This pattern allows each signal contact to be near a ground contact. Additionally, it positions ground contacts between signal contacts in adjacent rows. Such a configuration may be beneficial in controlling the impedance of the signal contacts and/or in reducing cross talk among the signal contacts.

Contacts such as 230₁ . . . 230₄ and 232₁ . . . 232₄ may be shaped to provide attachment to circuit board 130 according to any desired method. In the illustration of FIG. 2, the contacts are shaped for surface mounting. Each of the contacts has a portion that is generally coplanar with surface 124. When socket 120 is placed on circuit board 130, these portions of the contacts engage a solder brick (not shown) placed on pads 132 using surface mount equipment.

However, other forms of mounting may be used and the contacts may be shaped as appropriate for the desired mounting method. For example, contacts may be formed with conductive pads on them that may receive a solder ball for use with a BGA mounting method. For pressure mounting methods, the contacts may extend below surface 124 so that they are pressed into windows 210 when socket 120 is pressed against board 130.

In the described embodiment, the contacts are formed at one end of a conductive member within socket 120. Preferably, the conductive members include curved portions in the vicinity of the contacts. Curved portions in the conductive members may facilitate compliance in the mounting and reduce the effects of thermal cycling on socket 120.

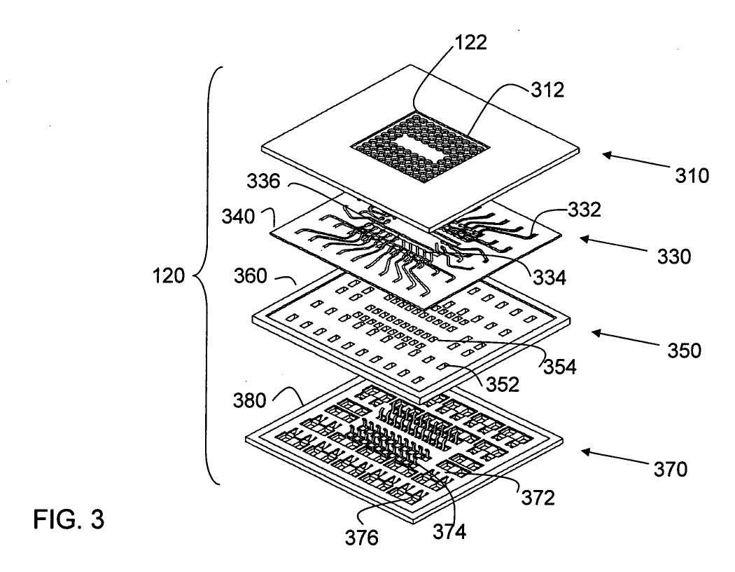

FIG. 3 shows an exploded view of socket 120. In this embodiment, socket 120 is made from four subassemblies: nest 310, signal lead frame 330, organizer 350 and ground lead frame 370. These subassemblies may be held together in any suitable fashion. For example, the subassemblies may be held together with epoxy or other adhesive. Alternatively, attachment features may be included on the subassemblies. Examples of attachment features are hubs and latches. Alternatively, socket 120 in its entirety or some subset of the subassemblies may be formed using an over molding process. In an over molding process, the housing or other structural components of one subassembly may be molded on top of or around another subassembly. The over molding process generally results in the subassemblies being affixed to each other.

Nest 310 forms the upper surface of socket 120. Nest 310 may be formed of an insulative material such as used in the formation of electrical connectors. Examples of suitable materials are LCP and nylon. In the described embodiment, nest 310 is molded as a separate component, but the structures of nest 310 could be formed as a part of another subassembly, such as signal lead frame 330.

Nest 310 is formed with cavity 122 in its upper surface. The specific size and shape of cavity 122 will depend on the specific chip that socket 120 is designed to receive. The floor of cavity 122 is formed with multiple holes 312 in it. Holes 312 pass through nest 310. Each of the holes 312 is designed to align with a solder ball 112 on the chip 110 to be received by socket 120. The number, size and placement of holes 312 may vary depending on the construction of the chip 110. When socket 120 is assembled, holes 312 receive the contact portions of conductors from within socket 120 and receive solder balls 112 from chip 110. Nest 310 aligns the contact portions with the solder balls 112 to ensure the contact portions make connection with the solder balls. Nest 310 also serves to separate the individual contacts and prevent them from shorting together.

Signal lead frame 330 includes multiple signal conductors 332. Each signal conductor 332 may be an elongated metal member. In the described embodiment, the signal conductors 332 are formed of a springy material of the type traditionally used to make contacts and electrical connectors. Examples of suitable materials are copper alloys and phosphor bronze.

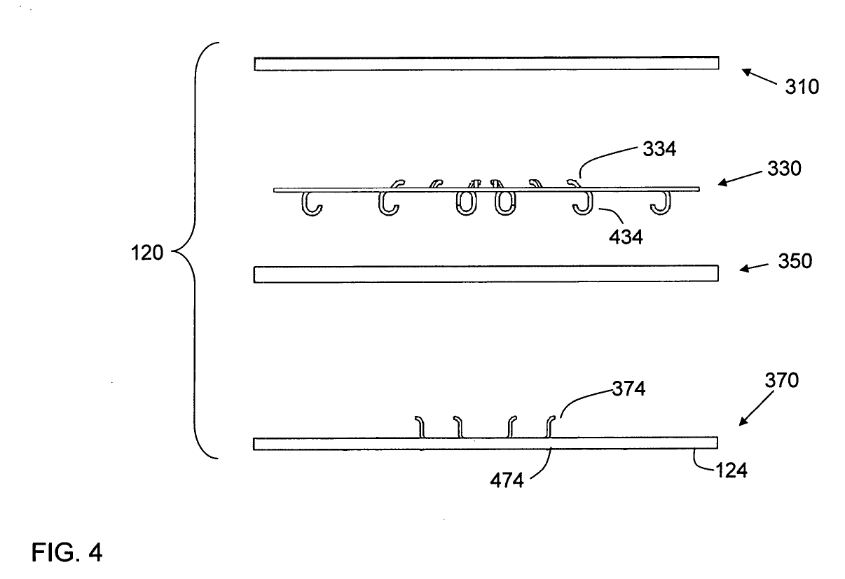

Forming signal conductors 332 of a springy, conductive material allows contact portions 334 and 434 (FIG. 4) to be formed at the ends of the signal conductors 332 by forming the signal conductors into the desired shape. However, the signal conductors may be formed of other materials and in other ways. For example, it is not necessary that the signal conductors and contact portions be formed from a single piece of metal. The contact portions could be attached to the signal conductor. One alternative is that signal conductors 332 may be formed by depositing or patterning a metal layer on a substrate similar to the way that conductive traces are formed in the manufacture of printed circuit boards. Contact portions may then be added to both sides of the substrate.

The number, shape and position of signal conductors 332 may depend on the specific design of the chip 110 that socket 120 is designed to receive. In the pictured embodiment, a contact portion 334 is positioned to align with each solder ball on chip 110 that generates or receives a signal, which impacts the number and placement of signal conductors 332.

The individual signal conductors 332 are held within housing 340. Housing 340 may be an insulative material insert molded around signal conductors 332. Insert molding techniques similar to those used to form waferized, board-to-board connectors may be used to form signal lead frame 330. In such an operation, the individual signal conductors 332 are stamped and formed from a sheet of metal. The stamping operation leaves portions of the sheet of metal as tie bars between the individual signal conductors 332. The tie bars allow the signal conductors 332 to be handled as a unit. This unit is positioned with intermediate portions of signal conductors 332 in the cavity of a mold. The material forming housing 340 is then injected into the mold. Stops around contact portions 334 and 434 prevent those portions from being covered by the housing material. When the signal lead frame 330 is removed from the mold, the tie bars may be severed to electrically isolate the individual signal conductors 332 from each other. The housing material holds the signal conductors 332 in place, while leaving contact portions 334 and 434 exposed for making contact to other structures.

In the pictured embodiment, all of the signal conductors 332 needed to make connections to solder balls 112 are routed within a single plane formed by signal lead frame 330. Where more connections are required between chip 110 and circuit board 130, signal conductors 332 may be routed in multiple layers. One way to form multiple layers of signal conductors is to include multiple subassemblies in the form of signal lead frame 330. Each signal lead frame subassembly could be formed with a different pattern of signals conductors to make contact to different ones of the solder balls 112.

Signal lead frame 330 includes one or more openings 336 to allow contact portions 374 from ground lead frame 370 to extend into nest 310.

Organizer 350 may also be molded from insulative material of the type traditionally used in the manufacture of electrical connectors. Organizer 350 includes an insulative body 360. Holes are formed through body 360 to receive the contact portions from signal lead frame 330 and ground lead frame 370. Contact portions 434 (FIG. 4) from signal lead frame 330 pass through holes such as 352 in organizer 350 to make connection with circuit board 130. Contact portions 374 from ground lead frame 370 pass through holes such as 354 to make contact with solder balls 112 on chip 110. Organizer 350 provides mechanical rigidity to socket 120 and ensures contact portions from signal lead frame 330 and ground lead frame 370 are properly aligned.

FIG. 3 shows organizer 350 formed separately from signal lead frame 330 and ground lead frame 370. Organizer 350 could alternatively be over molded on either signal lead frame 330 or ground lead frame 370. Alternatively, organizer 350 could be designed with channels to receive conductors such as signal conductors 332. Affixing signal conductors 332 to organizer 350 may avoid the need to form a separate signal lead frame subassembly 330. In some embodiments, organizer 350 may be omitted.

Ground lead frame 370 is formed from a conductive sheet 372. Conductive sheet 372 may also be a springy metal as is traditionally used in the manufacture of contacts for electrical connectors. Contact portions such as 374 and 474 (FIG. 4) may be stamped and formed from the sheet.

In addition, holes 376 are formed in sheet 372 to allow contact portions 434 (FIG. 4) from signal lead frame 330 to pass through ground lead frame 370 to make connections with circuit board 130. Ground lead frame 370 includes a housing 380 that may be molded around sheet 372. Holes 210 (FIG. 2) are formed in housing 380 to allow contact portions to reach circuit board 130. Housing 380 may be insert molded around sheet 372 using techniques and materials employed in the manufacture of electrical connectors or in any other suitable way.

Sheet 372 is shown in an embodiment in which it is generally parallel to signal conductors 332 throughout the body of socket 120. This arrangement contributes to the signal integrity of socket 120. In some embodiments, sheet 372 is connected to ground during operation of socket 120. By providing a sheet-like ground structure parallel to signal conductors 332, each signal conductor forms a structure resembling a microstrip transmission line. A microstrip transmission line may be desirable because it has a controlled impedance and reduces cross-talk. Spacing between signal conductors 332 and sheet 372 may be varied to control the impedance of signal conductors 332.

FIG. 4 shows a side view of socket 120. Contact portions 334 project upwards from the signal lead frame 330 so that they may engage solder balls 112 within holes 312 of nest 310. Contact portions 334 are formed as cantilever beams that will deflect when a chip 110 is pressed into socket 120. Deflection of the contact portions 334 will generate the required mating force to ensure a good electrical connection between the signal conductors 332 and solder balls 112. However, contact portions 334 may be formed in other shapes, including posts that may penetrate a solder ball when chip 110 is pressed into socket 120 or forks that may press on opposing surfaces of a solder ball.

Contact portions 434 are shown extending downward from signal lead frame 330. Contact portions 434 extend through organizer 350 and ground lead frame 370 to lower surface 124. Contact portions 434 are bent to form a portion that will be positioned near lower surface 124 and will be suitable for soldering to circuit board 130. Contact portions 434 are also shaped liked cantilever beams. This shape of contact portions 434 will allow compliant motion of contact portions 434 to adjust to the height of solder or other mounting structures on circuit board 130. Curved portions may also be formed in contact portions 434 to provide more compliance. The compliant nature of contact portions 434 will also reduce stress on any connection between contact portions 434 and circuit board 130 caused by thermal cycling.

Contact portions 374 are shown extending upwards from ground lead frame 370. Contact portions 374 extend through organizer 350 and signal lead frame 330 so that they may engage solder balls 112 within nest 310. Contact portions 374 may be shaped similarly to contact portions 334, but are longer to reach solder balls 112 from ground lead frame 370.

In the embodiment shown, the contact portions 334 of signal conductors 332 are positioned in rows. Likewise, contact portions 374 from ground lead frame 370 are positioned in rows. The rows of contact portions 374 from ground lead frame 370 are positioned between the rows of contact portions 334 from signal lead frame 330. This positioning improves the signal integrity of socket 120 by controlling impedance and reducing cross talk between signal conductors.

Contact portions 474 extend from lower surface 124. In the illustrated embodiment, contact portions 474 are substantially parallel with lower surface 124 and only a very small portion of the contact portions 474 is visible in the view of FIG. 4. Such a configuration is suitable for making a surface mount connection to circuit board 130.

Having thus described several aspects of at least one embodiment of this invention, it is to be appreciated that various alterations, modifications, and improvements will readily occur to those skilled in the art.

For example, subassemblies are shown to be flat, generally planar structures. Such subassemblies are readily aligned side-by-side for incorporation into assemblies. However, there is no requirement that the major surfaces of each subassembly be flat. Even if the surfaces are manufactured to be generally planar, they may be formed with projections, recesses or other features that facilitate attachment of subassemblies.

As another example, socket 120 is shown manufactured from multiple subassemblies that are secured together and then mounted to circuit board 130. It is not necessary that the subassemblies be fixedly attached to each other. A socket could be formed with one portion attached to a circuit board, such as through soldering. A second portion could be designed to receive the chip. The two portions could then be connected using separable electrical connections.

Also, the described embodiment shows a ground structure formed from a single sheet of metal. A similar structure could be formed from multiple separate contact members.

Further, it is not necessary that the signal and ground conductors be formed on separate sub-assemblies. Some of the signal conductors 332 could be connected to ground. In this configuration, a separate ground lead frame could be omitted. One or more signal lead frames could be used in this configuration.

Also, it was described that multiple signal lead frames could be used to provide more connections between a chip and a circuit board than can be conveniently provided in a single signal lead frame. The signal lead frames may be positioned on opposite sides of the ground lead frame. Where multiple signal lead frames are provided, multiple ground lead frames may also be provided. In one embodiment, the lead frames are stacked in an alternating fashion, with a ground lead frame positioned between adjacent pairs of signal lead frames.

Further, a socket according to the invention is illustrated as receiving a flip chip with microballs. Contact portions 334 and 374 are accordingly shaped to make an electrical connection to solder balls. Chip 110 could have leads of different construction. For example, connections to chip 110 could be made through pads that do not contain solder balls. Contact portions 334 or 374 may have the shape illustrated or a different shape to make connection to chips with leads shaped other than as solder balls.

Such alterations, modifications, and improvements are intended to be part of this disclosure, and are intended to be within the spirit and scope of the invention. Accordingly, the foregoing description and drawings are by way of example only.

What is claimed is:

1. A method of manufacturing a chip socket comprising:
a) providing a plurality of conductive members, each having a first contact portion, a second contact portion and an intermediate portion coupled between the first contact portion and the second contact portion;
b) molding insulative material over the intermediate portions of the plurality of conductive members, the insulative material shaped with a first surface and a second surface, opposite the first surface, the insulative material molded to leave the first contact portions of each of the plurality of conductive members exposed in the first surface of the insulative material and to leave the second contact portions of each of the plurality of conductive members exposed in the second surface of the insulative material.

2. The method of manufacturing a chip socket of claim 1, wherein the intermediate portions of the plurality of conductive members are disposed in a plane, the method additionally comprising providing a planar member parallel to the plane, the planar member having a first major surface and a second major surface, a first plurality of contact portions and a second plurality of contact portionse.

3. The method of manufacturing a chip socket of claim 2, wherein providing a planar member comprises stamping and forming a piece of metal to form the first plurality of contact portions extending through the first major surface and the second plurality of contact portions extending through the second major surface.

4. The method of manufacturing a chip socket of claim 3, wherein providing a planar member additionally comprises molding insulative material over the piece of metal.

5. The method of manufacturing a chip socket of claim 4, additionally comprising mechanically coupling the insulative material molded over the piece of metal to the insulative material molded over the intermediate portions of the plurality of conductive members.

6. The method of manufacturing a chip socket of claim 1, additionally comprising forming a second contact portion on each of the plurality of conductive members by attaching a solder ball to the conductive member.

7. A method of manufacturing a chip socket, comprising:
a) forming a first subassembly according to the method of claim 1;
b) forming a second subassembly by molding a second layer of insulative material over conductive material, the conductive material comprising a plurality of third contact portions, the second layer of insulative material having a plurality of openings therethrough; and
c) aligning the first subassembly and the second subassembly, with the second contact portions of the first subassembly positioned within the openings of the second layer of insulative material.

8. A chip socket comprising:
a) an insulative housing; and
b) a plurality of conductive members, each having a first contact portion and a second contact portion and an intermediate portion coupled between the first contact portion and the second contact portion, wherein the plurality of conductive members are positioned with the intermediate portions of the plurality of conductive members disposed in a plane within the insulative housing and the first contact portion of each of the plurality of conductive members extending from the plane in a first direction and the second contact portion of each of the plurality of conductive members extending from the plane in a second direction, opposite the first direction.

9. The chip socket of claim 8, wherein the insulative housing has a first planar surface and a second planar surface and the first contact portions of the conductive members are accessible through the first surface and the second contact portions are accessible through the second surface.

10. The chip socket of claim 8, adapted to interface to a chip having a surface with a pattern of contacts thereon, wherein the first contact portions of the plurality of conductive members are aligned with the pattern of contacts on the chip.

11. The chip socket of claim 10, wherein the insulative housing has a plurality of holes formed therein, with the holes aligned with the pattern of contacts on the chip and the first contact portions are positioned within the holes.

12. The chip socket of claim 8, wherein the insulative housing comprises a chip receiving cavity and a cover for the chip receiving cavity.

13. The chip socket of claim 12, wherein the cover is metal.

14. The chip socket of claim 8, wherein the insulative housing comprises a first housing layer and a second housing layer and the intermediate portions of the plurality of conductive members are encapsulated in the first housing layer and the second housing layer comprises a plurality of windows therethrough, with each of the first contact portions disposed in one of the plurality of windows.

15. The chip socket of claim 14, further comprising a conductive structure disposed within the second housing layer, the conductive structure comprising contact portions extending therefrom, and a planar portion parallel to the plane.

16. A chip socket comprising:
a) a plurality of conductive members, each of the plurality of conductive members having an first contact portion, a second contact portion and an intermediate portion coupled between the first contact portion and the second contact portion, with the intermediate portions of the plurality of conductive members disposed in a first plane with the first contact portion of each of the plurality of conductive members extending in a first direction and the second contact portion of each of the plurality of conductive members extending in a second direction; and
b) a conductive structure having a portion positioned in a second plane parallel to the first plane, the conductive structure having a plurality of first contact portions and a plurality of second contact portions, with the plurality of first contact portions extending in the first direction and the plurality of second contact portions extending in the second direction.

17. The chip socket of claim 16, wherein the conductive structure comprises a sheet of material.

18. The chip socket of claim 16, wherein the conductive structure comprises a plurality of separate conducting members.

19. An electronic assembly, comprising:
a) the chip socket of claim 16;
b) a printed circuit board having a surface with a plurality of signal contact points formed thereon and a plurality of ground contact points thereon; and
c) wherein each of the second contact portions of the plurality of conductive members is coupled to a signal contact point and each of the second contact portions of the conductive structure is coupled to a ground contact point.

20. The electronic assembly of claim 19, additionally comprising solder coupling each of the second contact portions of the plurality of conductive members to a signal contact point and each of the second contact portions of the conductive structure to a ground contact point.

21. The chip socket of claim 16, wherein the first contact portions of each of the plurality of conductive members are disposed in a plurality of rows and the first contact portions of the conductive structure are disposed in a plurality of rows, with rows of first contact portions of the conductive structure positioned between rows of first contact portions of the plurality of conductive members.

22. The chip socket of claim 16, wherein:
a) the first contact portions of each of the plurality of conductive members and the first contact portions of the conductive structure each occupies a position of a first rectangular array with spacing of less than 0.9 mm between positions of the first rectangular array; and
b) the second contact portions of each of the plurality of conductive members and the second contact portions of the conductive structure each occupies a position of a second rectangular array with spacing of 0.9 mm or more between positions of the second rectangular array.

23. The chip socket of claim 16, additionally comprising an insulative housing portion and wherein the intermediate portions of the plurality of conductive contact members are positioned within the insulative housing.

24. The chip socket of claim 23, additionally comprising a second housing portion and a second plurality of conductive members, each of the second plurality of conductive members having a first contact portion and a second contact portion and an intermediate portion coupled between the first contact portion and the second contact portion with the intermediate portions of the second plurality of conductive members disposed in the second housing portion.
